(19) United States
(12) Patent Application Publication
(10) Pub. No.: US 2007/0037412 A1
(43) Pub. Date: Feb. 15, 2007

(54) IN-SITU ATOMIC LAYER DEPOSITION

(75) Inventors: Anthony Dip, Cedar Creek, TX (US); Sadao Sasaki, Austin, TX (US); Michael Toeller, Austin, TX (US); Kimberly G. Reid, Austin, TX (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: TOKYO ELECTRON LIMITED, Tokyo (JP)

(21) Appl. No.: 11/462,234

(22) Filed: Aug. 3, 2006

Related U.S. Application Data
(60) Provisional application No. 60/706,173, filed on Aug. 5, 2005.

(51) Int. Cl. H01L 21/31

(52) U.S. Cl. 438/785

(57) ABSTRACT

An in situ method for forming a HfO₂ high-k dielectric layer in a batch wafer processing system. The method comprises first loading a plurality of wafers into a process chamber, and then pre-treating the plurality of wafers in the process chamber with a first oxidizer. After pre-treating the wafers, and without removing the wafers from the process chamber, the method then comprises depositing HfO₂ on the plurality of wafers by atomic layer deposition, which comprises a plurality of deposition cycles, each cycle comprising alternating exposure of the plurality of wafers in the process chamber to a second oxidizer and a hafnium precursor. The hafnium precursor is selected from hafnium tert-butoxide (HTB) or hafnium tetra-diethylamide (TDEAH).

### FIELD OF THE INVENTION

This invention relates to atomic layer deposition of an HfO₂ high-k dielectric layer, and more particularly to an in-situ process including pre-oxidation, atomic layer deposition of the HfO₂ dielectric layer, and a post-deposition anneal.

### BACKGROUND OF THE INVENTION

Several methods have been developed for creating thin films on substrates used in manufacturing semiconductor devices. Among the more established techniques is Chemical Vapor Deposition (CVD). Atomic Layer Deposition (ALD), a variant of CVD, is a relatively newer technology now emerging as a potentially superior method of achieving uniform, conformal film deposition.

ALD has demonstrated an outstanding ability to maintain ultra-uniform thin deposition layers over complex topology. This is at least partially true because ALD is not as flux dependent as is CVD. This flux-independent nature of ALD allows processing at lower temperatures than with conventional CVD methods.

The technique of ALD is based on the principle of the formation of a saturated monolayer of reactive precursor molecules by chemisorption. It may thus also be referred to as molecular layer deposition (MLD). A typical ALD process for forming an AB film, for example, on a substrate consists of injecting a precursor or reactant A (R_{A}) for a period of time in which a saturated monolayer of A is formed on the substrate. Then, the precursor or reactant A (R_{A}) is purged from the chamber using an inert gas, G_{I}. This is followed by injecting precursor or reactant B (R_{B}) into the chamber, also for a period of time, to combine B with A thus forming the layer AB on the substrate. Then, the precursor or reactant B (R_{B}) is purged from the chamber. This process of introducing precursor or reactant A (R_{A}), purging the reactor, introducing precursor or reactant B (R_{B}), and purging the reactor can be repeated a number of times to achieve an AB film of a desired thickness.

In the semiconductor industry, the minimum feature sizes of microelectronic devices are well into the deep sub-micron regime to meet the demand for faster, and lower power semiconductor devices. The downscaling of complimentary metal-oxide-semiconductor (CMOS) devices imposes scaling constraints on the gate dielectric material. The thickness of the conventional SiO₂ gate dielectric is approaching its physical limits. The most advanced devices are using nitrided SiO₂ gate dielectrics approaching equivalent oxide thickness (EOT) of about 1 nanometer (nm) or less where the leakage current density can be as much as 1 mA/cm². To improve device reliability and reduce electrical leakage from the gate dielectric to the transistor channel during operation of the device, semiconductor transistor technology is planning on using high dielectric constant (high-k) gate dielectric materials that allow increased physical thickness of the gate dielectric layer while maintaining a low equivalent oxide thickness (EOT). Equivalent oxide thickness is defined as the thickness of SiO₂ that would produce the same capacitance voltage curve as that obtained from an alternate dielectric material.

Dielectric materials featuring a dielectric constant greater than that of SiO₂ (k˜3.9) are commonly referred to as high-k materials. High-k materials may refer to dielectric materials that are deposited onto substrates (e.g., HfO₂, ZrO₂, HfSiO, ZrSiO, etc) rather than grown on the surface of the substrate, as is the case for SiO₂. High-k materials may incorporate a metal oxide layer or a metal silicate layer, e.g., Ta₂O₅ (k˜26), TiO₂ (k˜80), ZrO₂ (k˜25), Al₂O₃ (k˜9), HfSiO (k˜5-20), and HfO₂ (k˜25).

In the deposition of high-k dielectrics, such as HfO₂, an ex-situ ALD process has been used where pre-treatments, deposition, and post-treatments are each carried out in a separate system, with the wafers being unloaded from one system, transferred to the next, and loaded in that system for the next processing. With each transfer of the wafers, contamination can occur. In addition, without the post-treatment, the deposited dielectric layer is undensified, and may be harmed by exposure to air during the wafer transfer from the deposition system to the post-treatment system. In addition to the need to reduce wafer contamination, there is further a need to achieve good uniformity in batch processing, with respect to zone-to-zone uniformity, wafer-to-wafer uniformity and overall film uniformity. In addition to the need for good film uniformity, there is also a need to improve the electrical properties of the high-k dielectric film, including the amount of hysteresis in the film, the density of defects at the interface, and the leakage current while maintaining a high effective k value for the film stack and a low EOT.

### SUMMARY OF THE INVENTION

The invention provides an in situ method for forming a HfO₂ high-k dielectric layer with good uniformity and good electrical properties in a batch wafer processing system, where the wafers are not transferred between process chambers between pre-deposition oxidation treatments, atomic layer deposition, and post-deposition annealing. The method of the invention comprises first loading a plurality of wafers into a process chamber, and then pre-treating the plurality of wafers in the process chamber with a first oxidizer selected from an oxygen-containing gas or an oxygen- and nitrogen-containing gas. After pre-treating the wafers, and without removing the wafers from the process chamber, the method then comprises depositing HfO₂ on the plurality of wafers by atomic layer deposition. The atomic layer deposition comprises a plurality of deposition cycles, each cycle comprising alternating exposure of the plurality of wafers in the process chamber to a second oxidizer and a hafnium precursor with optional purging in-between. The second oxidizer is selected from an oxygen-containing gas or an oxygen- and nitrogen-containing gas, and the hafnium precursor is selected from hafnium tert-butoxide (HTB) or hafnium tetra-diethylamide (TDEAH). After deposition, the wafers are unloaded from the process chamber.

In one embodiment of the invention, after the depositing, and without removing the plurality of wafers from the process chamber, the plurality of wafers are annealed to densify the HfO₂. The annealing is selected from one or any sequential combination of a bake with no gaseous environment, an oxidation anneal in the presence of a third oxidizer selected from an oxygen-containing gas or an oxygen- and nitrogen-containing gas, or an anneal in the presence of a non-oxidizing gas.

### BRIEF DESCRIPTION OF THE DRAWINGS

A more complete appreciation of the invention and many of the attendant advantages thereof will become readily apparent with reference to the following detailed description, particularly when considered in conjunction with the accompanying drawings, in which:

FIG. 1A shows a simplified block diagram of a batch-type processing system according to an embodiment of the invention;

FIG. 1B shows a simplified block diagram of another batch-type processing system according to an embodiment of the invention;

FIG. 2 shows a simplified block diagram of a gas injection system coupled to a process chamber according to an embodiment of the invention;

FIGS. 3A and 3B graphically depict a timeline for an in situ molecular layer batch deposition process of the invention and an ex situ molecular layer batch deposition process of the prior art, respectively;

FIG. 4 depicts the chemical structures and formulas for hafnium tert-butoxide (HTB) and hafnium tetra-diethylamide (TDEAH);

FIGS. 5A-5B graphically depict thickness uniformity for the HTB precursor;

FIGS. 6A-6B graphically depict thickness uniformity for the TDEAH precursor;

FIGS. 7A-7B graphically depict capacitance versus voltage (CV) for an HfO₂ film deposited from HTB with O₂ and nitric oxide, respectively, as the oxidizer;

FIG. 8 graphically depicts the effect on the CV due to pre-oxidation and/or post-oxidation in an HTB:O₂ MLD process;

FIG. 9 graphically depicts CV for an HfO₂ film deposited from TDEAH with H₂O vapor as the oxidizer;

FIG. 10 graphically depicts the change in the amount of hysteresis (Delta Vfb) and the Density of Defects at the Interface (Dit) as a function of post-deposition anneal (PDA) temperature for an HfO₂ film deposited from TDEAH with H₂O vapor as the oxidizer;

FIGS. 11A-11B graphically depict change in CV as a function of length of PDA for an HfO₂ film deposited from TDEAH with H₂O vapor as the oxidizer;

FIGS. 12A-12B graphically depict thickness uniformity as a function of oxidizer type for the TDEAH precursor;

FIGS. 13A-13D graphically depict CV as a function of oxidizer type for the TDEAH precursor;

FIGS. 14A-14D graphically depict CV as a function of number of cycles for the TDEAH precursor with H₂O vapor as the oxidizer; and

FIG. 15 graphically depicts physical thickness, EOT, dielectric constant (K value) and leakage current density (J_{L}) as a function of number of cycles for the TDEAH precursor with H₂O vapor as the oxidizer.

### DETAILED DESCRIPTION

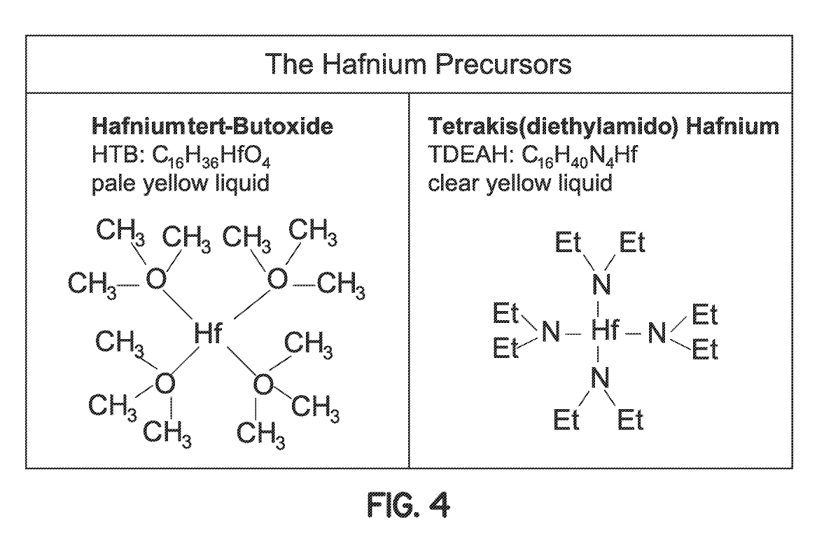

The present invention is directed to in-situ atomic layer deposition of an HfO₂ high-k dielectric layer in a batch wafer processing system. The process includes a pre-oxidation treatment, followed by deposition by alternate exposures to an oxidizer and a hafnium tert-butoxide (HTB) or hafnium tetra-diethylamide (TDEAH) precursor, the structures of which are depicted in FIG. 4. The chamber may be purged between oxidizing and precursor exposure, and between repeating cycles of exposure to the oxidizer and precursor, and the cycles may be repeated a desired number of times. The purging process may use an inert gas, for example, such as H₂ or Ar. The purge time may be any desired time for removing excess reactant from the chamber, for example, about 10 seconds to about 5 minutes, and by way of further example, about 30 seconds to about 2 minutes.

The oxidizer for the pre-oxidization treatment and for the deposition may be the same or different, and may be an oxygen-containing gas, or a nitrogen/oxygen-containing gas, for example. In an exemplary embodiment, the oxidizer is one of the following: O₂, O₃, N₂O, NO, or H₂O vapor. The oxidizer may be delivered to the process chamber by known methods. In an exemplary embodiment, a water vapor generator is used to generate water vapor and deliver (or pulse) it to the process chamber as the oxidizer. The hafnium precursor may be HTB or TDEAH. In an exemplary embodiment, the hafnium precursor is TDEAH. In an exemplary embodiment, a liquid delivery system is used to deliver (or pulse) a vapor of the precursor to the process chamber. A pump coupled to an automatic pressure control with appropriate valving may be used, as is known in the art, to purge the chamber between cycles.

In one embodiment, the substrate (wafer) temperature during the pre-oxidation treatment is in the range of about 500-1000° C., such as about 600-850° C. Exemplary pre-oxidation treatments include exposure to NO at about 700° C. or about 800° C. The pre-oxidation may be performed for any desired amount of time. By way of example and not limitation, the pre-oxidation may be performed for about 30 seconds up to about 30 minutes, or about 5-20 minutes, for example about 10 minutes. A flow rate for the oxidizer may be up to about 20 slm, for example, about 0.1-5 slm. In an alternative embodiment, a low temperature pre-oxidation treatment may be carried out, for example at a temperature below about 500° C., such as about 250-450° C.

The atomic (molecular) layer deposition (ALD or MLD) may be carried out under conditions known in the art. For example, the chamber pressure may be in the range of about 0.001 mTorr to about 600 Torr. In an exemplary embodiment, the chamber pressure is 0.01 mTorr to about 100 Torr, for example about 0.1 to about 10 Torr. In a further exemplary embodiment, a chamber pressure of about 0.3 Torr may be used. The pressure in the chamber may be the same throughout the in-situ pre-oxidation, ALD, and post-deposition anneal. Alternatively, the pressure may vary.

The substrate temperature during the ALD process may be in the range of about 25-800° C., for example, about 50-600° C. In an exemplary embodiment, the substrate temperature may be in the range of about 100° C. to about 500° C., for example, about 175° C. to about 350° C. In an exemplary process, a hot-wall chamber processing system is used, in which case the chamber temperature will be at or near the substrate temperature.

A flow rate of up to about 20 slm, for example, about 0.1-5 slm may be used for the oxidizer and precursor during the ALD process. The exposure (or pulsing) time for the oxidizer and the precursor may each be in the range of about 5 seconds to about 5 minutes, for example, about 15 seconds to about 2 minutes. In an exemplary embodiment for forming HfO₂, the oxidizer is pulsed for twice as long as the hafnium precursor. The number of cycles, the flow rates, and exposure times may be dependent, at least in part, upon the desired film thickness. By way of example only, the process may include about 5-50 cycles of alternating pulsing of the oxidizer and hafnium precursor, for example about 10-25 cycles.

Once the desired number of cycles of alternating exposure to the oxidizer and precursor are carried out, a post-deposition anneal may be performed to densify the film stack. The post-deposition anneal may be a high temperature bake, a post-oxidation anneal, or a high temperature anneal in the presence of a non-oxidizing gas, such as N₂. In one embodiment, the substrate temperature during the post-deposition anneal is in the range of about 500-1000° C., such as about 550-800° C. Exemplary post-deposition anneals include exposure to NO at about 600° C. or exposure to N₂ at about 800° C. The anneal may be performed for any desired amount of time. By way of example and not limitation, the anneal may be performed for about 30 seconds up to 30 minutes, or about 5-20 minutes, for example about 10 minutes. In an alternative embodiment, a low temperature post-deposition anneal may be carried out, for example at a temperature below about 500° C., such as about 250-450° C. In either embodiment, a flow rate of up to about 20 slm, for example about 0.1-5 slm, may be used for the oxidation gas or non-oxidizing gas.

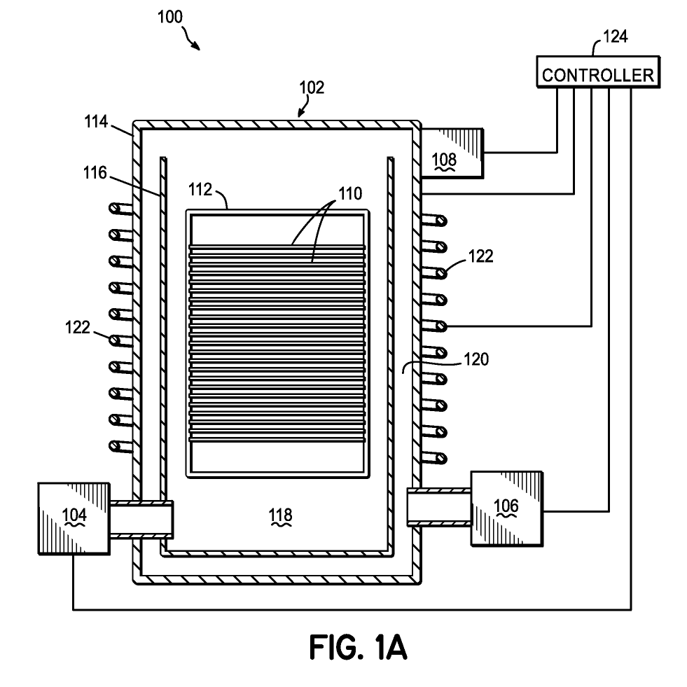

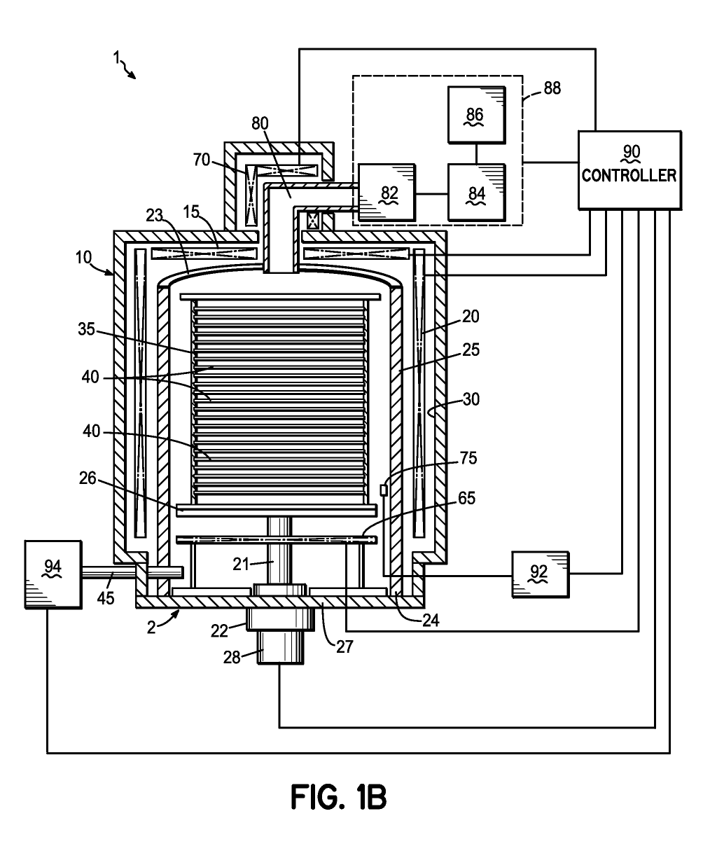

FIG. 1A shows a simplified block diagram of a batch-type processing system for forming a HfO₂ dielectric layer on a substrate according to an embodiment of the invention. The batch-type processing system 100 includes a process chamber 102, a gas injection system 104, a heater 122, a vacuum pumping system 106, a process monitoring system 108, and a controller 124. Multiple substrates 110 can be loaded into the process chamber 102 and processed using substrate holder 112, also referred to as a wafer boat. Furthermore, the process chamber 102 comprises an outer section 114 and an inner section 116. In one embodiment of the invention, the inner section 116 can be a process tube.

The gas injection system 104 can introduce gases into the process chamber 102 for purging the process chamber 102, and for preparing, cleaning, and processing the substrates 110. The gas injection system 104 can, for example, include a liquid delivery system (LDS) (not shown) that contains a vaporizer to vaporize a precursor liquid such as HTB or TDEAH. The vaporized liquid can be flowed into the process chamber 102 with or without the aid of a carrier gas. For example, when a carrier gas is used, the gas injection system can include a bubbling system where the carrier gas is bubbled through a reservoir containing the precursor liquid. In addition, the gas injection system 104 can be configured for flowing a gaseous Si-containing gas, e.g., silane (SiH₄), from a high-pressure container to form a Si layer upon which the HfO₂ dielectric will be formed. Furthermore, the above-mentioned gas flows can, for example, contain an inert gas and/or a hydrogen-containing gas. The hydrogen-containing gas can, for example, contain H₂. Gas injection system 104 may also include an oxidizing gas source (not shown) and/or a water vapor generator (WVG) (not shown). A plurality of gas supply lines can be arranged to flow gases into the process chamber 102. The gases can be introduced into volume 118, defined by the inner section 116, and exposed to substrates 110. Thereafter, the gases can flow into the volume 120, defined by the inner section 116 and the outer section 114, and exhausted from the process chamber 102 by the vacuum pumping system 106.

Substrates 110 can be loaded into the process chamber 102 and processed using substrate holder 112. The batch-type processing system 100 can allow for a large number of tightly stacked substrates 110 to be processed, thereby resulting in high substrate throughput. A substrate batch size can, for example, be about 100 substrates (wafers), or less. Alternately, the batch size can be about 25 substrates, or less. The process chamber 102 can, for example, process a substrate of any size, for example 200 mm substrates, 300 mm substrates, or even larger substrates. The substrates 110 can, for example, comprise semiconductor substrates (e.g. silicon or compound semiconductor), LCD substrates, and glass substrates.

The batch-type processing system 100 can be controlled by a controller 124 capable of generating control voltages sufficient to communicate and activate inputs of the batch-type processing system 100 as well as monitor outputs from the batch-type processing system 100. Moreover, the controller 124 can be coupled to and exchange information with process chamber 102, gas injection system 104, heater 122, process monitoring system 108, and vacuum pumping system 106. For example, a program stored in the memory of the controller 124 can be utilized to control the aforementioned components of the batch-type processing system 100 according to a stored process recipe. One example of controller 124 is a DELL PRECISION WORKSTATION 610™, available from Dell Corporation, Dallas, Tex.

Real-time process monitoring can be carried out using process-monitoring system 108. In general, the process monitoring system 108 is a versatile monitoring system and can, for example, comprise a mass spectrometer (MS) or a Fourier Transform Infra-red (FTIR) spectrometer. The process monitoring system 108 can provide qualitative and quantitative analysis of the gaseous chemical species in the process environment. Process parameters that can be monitored include gas flows, gas pressure, ratios of gaseous species, and gas purities. These parameters can be correlated with prior process results and various physical properties of the deposited HfO₂ film.

FIG. 1B shows a simplified block diagram of another batch-type processing system for forming a HfO₂ film on a substrate according to an embodiment of the invention. The batch-type processing system 1 contains a process chamber 10 and a process tube 25 that has a upper end connected to a exhaust pipe 80, and a lower end hermetically joined to a lid 27 of cylindrical manifold 2. The exhaust pipe 80 discharges gases from the process tube 25 to a vacuum pumping system 88 to maintain a pre-determined atmospheric or below atmospheric pressure in the processing system 1. A substrate holder 35 for holding a plurality of substrates (wafers) 40 in a tier-like manner (in respective horizontal planes at vertical intervals) is placed in the process tube 25. The substrate holder 35 resides on a turntable 26 that is mounted on a rotating shaft 21 penetrating the lid 27 and driven by a motor 28. The turntable 26 can be rotated during processing to improve overall film uniformity or, alternately, the turntable can be stationary during processing. The lid 27 is mounted on an elevator 22 for transferring the substrate holder 35 in and out of the reaction tube 25. When the lid 27 is positioned at its uppermost position, the lid 27 is adapted to close the open end of the manifold 2.

A plurality of gas supply lines can be arranged around the manifold 2 to supply a plurality of gases into the process tube 25 through the gas supply lines. In FIG. 1B, only one gas supply line 45 among the plurality of gas supply lines is shown. The gas supply line 45 is connected to a gas injection system 94. A cylindrical heat reflector 30 is disposed so as to cover the reaction tube 25. The heat reflector 30 has a mirror-finished inner surface to suppress dissipation of radiation heat radiated by main heater 20, bottom heater 65, top heater 15, and exhaust pipe heater 70. A helical cooling water passage (not shown) is formed in the wall of the process chamber 10 as a cooling medium passage.

A vacuum pumping system 88 comprises a vacuum pump 86, a trap 84, and automatic pressure controller (APC) 82. The vacuum pump 86 can, for example, include a dry vacuum pump capable of a pumping speed up to 20,000 liters per second (and greater). During processing, gases can be introduced into the process chamber 10 via the gas injection system 94 and the process pressure can be adjusted by the APC 82. The trap 84 can collect unreacted precursor material and by-products from the process chamber 10.

The process monitoring system 92 comprises a sensor 75 capable of real-time process monitoring and can, for example, comprise a MS or a FTIR spectrometer. A controller 90 includes a microprocessor, a memory, and a digital I/O port capable of generating control voltages sufficient to communicate and activate inputs to the processing system 1 as well as monitor outputs from the processing system 1. Moreover, the controller 90 is coupled to and can exchange information with gas injection system 94, motor 28, process monitoring system 92, heaters 20, 15, 65, and 70, and vacuum pumping system 88. As with the controller 124 of FIG. 1A, the controller 90 may be implemented as a DELL PRECISION WORKSTATION 610™.

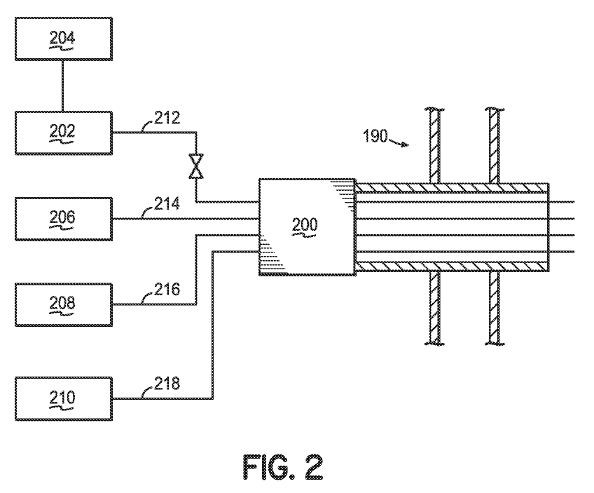

FIG. 2 depicts a gas injection system 200 coupled to a process chamber 190, where the gas injection system 200 and process chamber 190 can be the gas injection system 104 and process chamber 102 in FIG. 1A or the gas injection system 94 and process chamber 10 in FIG. 1B. Gas injection system 200 can be coupled to a liquid delivery system (LDS) 202 that contains a vaporizer to vaporize a precursor liquid such as HTB or TDEAH. The vaporized liquid can be flowed through the gas injection system 200 into the process chamber 190 with or without the aid of a carrier gas. For example, when a carrier gas is used, a bubbling system 204 may be provided where the carrier gas is bubbled through a reservoir containing the precursor liquid. In addition, the gas injection system 200 can be coupled to a Si-containing gas source 206, e.g., SiCl₄, SiH₄, or Si₂H₆, to provide gaseous Si to the process chamber 190 to form a Si layer upon which the HfO₂ dielectric will be formed. Gas injection system 200 may also include an oxidizing gas source 208 and/or a water vapor generator (WVG) 210. A plurality of gas supply lines 212, 214, 216, 218 can be arranged to flow the gases into the process chamber 190.

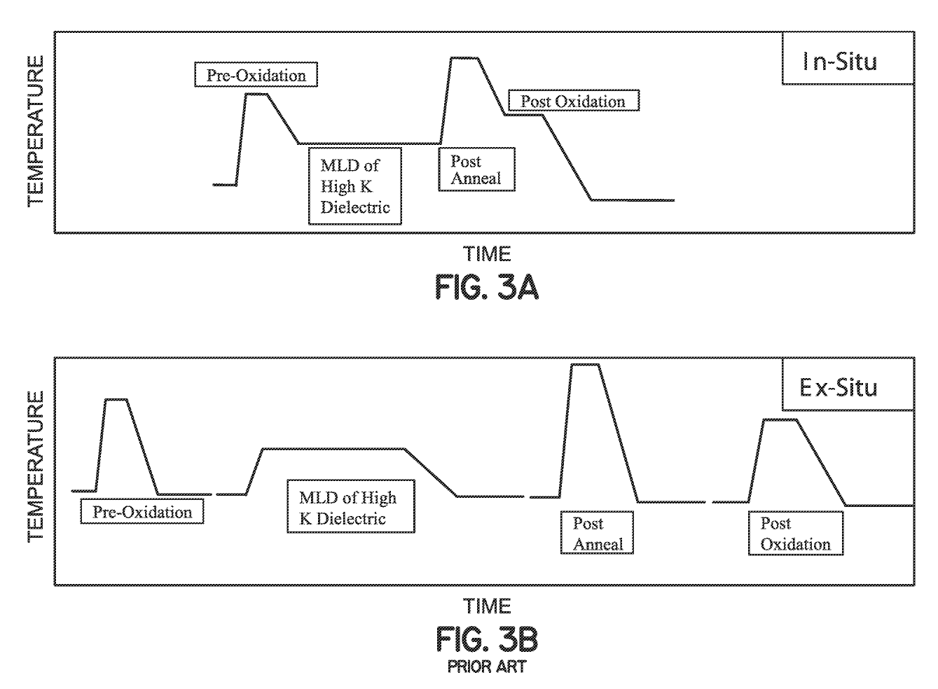

FIGS. 3A and 3B graphically and schematically depict a time versus temperature comparison of the in situ molecular layer batch deposition process of the invention to an ex situ molecular layer batch deposition process of the prior art. The in-situ pre-treatment and post-treatment of the invention saves time on loading and unloading wafers since they only need to be loaded once prior to pre-treatment and unloaded once after post-treatment, rather than the four loading and four unloading steps required in the prior art process. In addition, the in-situ pre-treatment and post-treatment of the invention saves time on temperature ramping, since the wafers need not be cooled down to a transfer temperature between steps. Finally, the in-situ pre-treatment and post-treatment of the invention saves time on wafer transport by eliminating the transport steps between processes. In addition to the time-savings, the in-situ pre-treatment and post-treatment of the invention reduces opportunities for contamination of thin interfaces, and can eliminate exposure of thin, undensified high-k films to air.

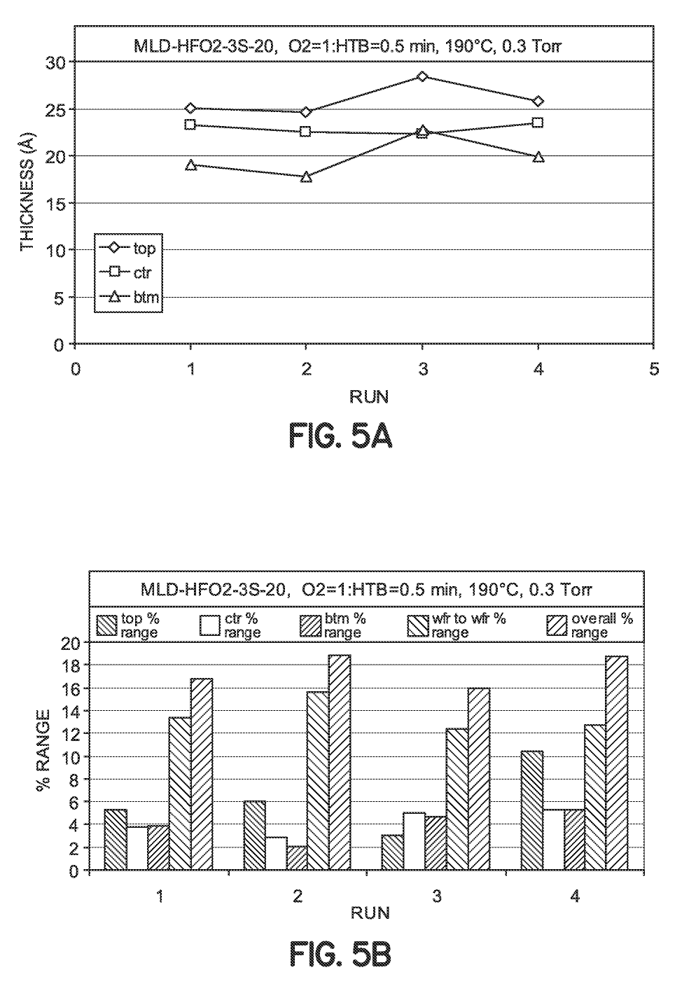

Referring to FIGS. 5A-5B, an MLD process of the invention was carried out using HTB as the precursor and O₂ as the oxidizer gas. There was no pre-treatment. Deposition was performed at a substrate temperature of 190° C. and a chamber pressure of 0.3 Torr. The O₂ was pulsed for 1 minute and alternated with a 0.5 minute pulse of HTB, and this alternating exposure cycle was repeated for a total of 20 cycles. Purge times between precursor and O₂ pulses, and between cycles, varied between 0.5 and 2 minutes. The in situ process had a total run time of about 4 hours and 20 minutes (excluding load and unload times). FIG. 5A plots the wafer thickness, in Angstroms, for wafers at the top, center and bottom of the wafer boat for several runs conducted at the conditions set forth above. FIG. 5B depicts in bar graph form the percent variability within each batch and overall, indicating good uniformity within each region of the wafer boat, but less than optimal uniformity from wafer-to-wafer within a batch and overall between batches.

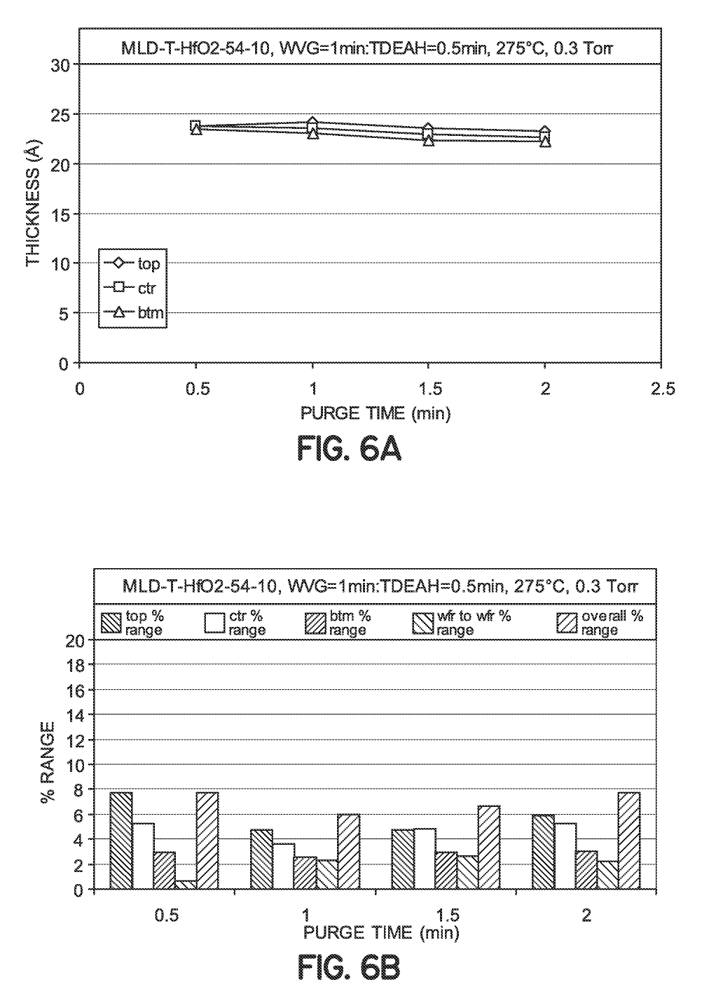

Referring to FIGS. 6A-6B, an MLD process of the invention was also carried out using TDEAH as the precursor and WVG as the oxidizer gas. There was no pre-treatment. Deposition was performed at a substrate temperature of 275° C. and a chamber pressure of 0.3 Torr. The WVG was pulsed for 1 minute and alternated with a 0.5 minute pulse of TDEAH, and this alternating exposure cycle was repeated for a total of 10 cycles, followed by a 10 minute post-deposition anneal in N₂ at 800° C. Purge times between precursor and WVG pulses, between cycles, and between the in situ steps, varied between 0.5 and 2 minutes. The in situ process had a total run time of about 4 hours and 30 minutes (excluding load and unload times). FIG. 6A plots the wafer thickness, in Angstroms, for wafers at the top, center and bottom of the wafer boat for varying purge times between 0.5 and 2 minutes. FIG. 6B depicts in bar graph form the percent variability within each batch and overall, indicating good uniformity within each region of the wafer boat, and good uniformity from wafer-to-wafer within a batch and overall between batches. From this data, it is believed that TDEAH generally provides more uniformity than HTB.

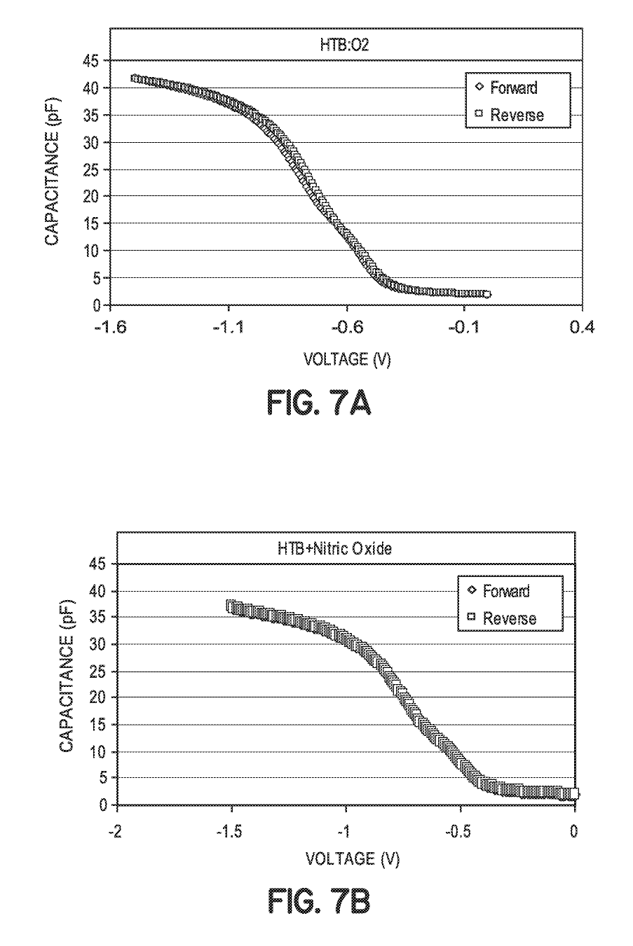

FIGS. 7A-7B graphically depict capacitance versus voltage (CV) for HfO₂ films deposited from HTB with O₂ and nitric oxide, respectively, as the oxidizer. For FIG. 7A, the deposition conditions were as described above with reference to FIG. 5A. For FIG. 7B, the conditions were identical except that nitric oxide was used in place of O₂. The resulting HfO₂ films exhibited good electrical properties in the as-deposited condition. In addition, using nitric oxide as the oxidizer increased the density of defects of the interface and removed the kink in the CV performance, as shown in FIG. 7B.

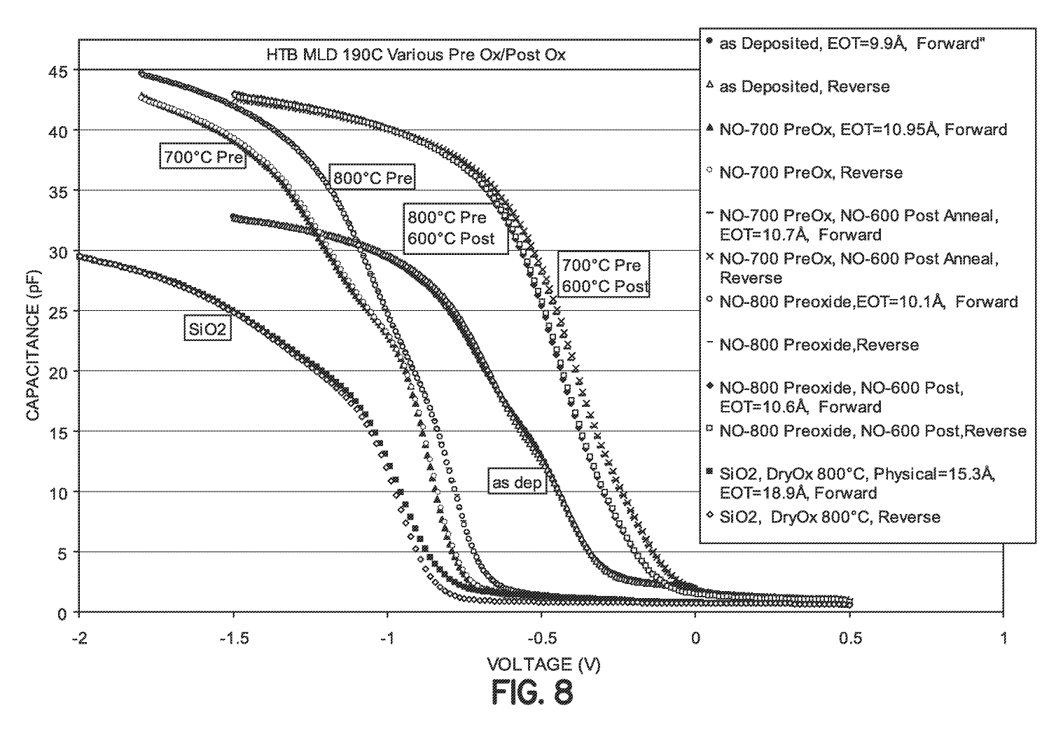

FIG. 8 graphically depicts the effect on the CV due to pre-oxidation and/or post-oxidation in an HTB:O₂ MLD process. The MLD process was carried out using HTB as the precursor and O₂ as the oxidizer gas. Deposition was performed at a substrate temperature of 190° C. and a chamber pressure of 0.3 Torr. The O₂ was pulsed for 1 min. and alternated with a 1 min. pulse of HTB for 20 cycles. For comparison, CV performance was also included for a SiO₂ dielectric layer deposited by conventional means and subjected to a dry oxidation treatment at 800° C. The results for the HTB:O₂ process of the invention are further set forth in the following table:

Pre and Post Oxidation of HTB:O₂ MLD

| | Pre ox | Pre Ox | | Post Ox | Post Ox | VASE | | | SSM | SSM 610 | SSM 610 | | Leakage |
|---|---|---|---|---|---|---|---|---|---|---|---|---|---|
| | Temp | Time | | Temp | Time | thickness | CV | SSM 610 | 610 | Delta Vfb | Dit (E12 | | Density |
| PreOx | (° C.) | (min) | Post Ox | (° C.) | (min) | (Å) | “kink” | EOT (Å) | Vfb (V) | (mVolts) | 1/cm3) | K value | at Vfb-1 |
| none | none | 0 | none | 0 | 0 | 24.2 | yes | 10.0 | −0.47 | 1.47 | 1.51 | 9.48 | 1.0E−02 |
| Nitric Oxide | 700 | 10 | none | 0 | 0 | 25.2 | yes | 11.0 | −0.79 | −7.14 | 1.74 | 8.97 | n.a. |
| Nitric Oxide | 800 | 10 | none | 0 | 0 | 25.5 | yes | 10.2 | −0.71 | 0.08 | 1.38 | 9.78 | n.a. |
| Nitric Oxide | 700 | 10 | Nitric | 600 | 10 | 23.9 | no | 10.7 | −0.16 | −4.06 | 1.12 | 8.71 | 1.4E−02 |
| | | | Oxide | | | | | | | | | | |
| Nitric Oxide | 800 | 10 | Nitric | 600 | 10 | 23.9 | no | 10.6 | −0.21 | −3.57 | 0.96 | 8.76 | 7.0E−03 |
| | | | Oxide | | | | | | | | | | |

VASE = Variable Angle Spectral Ellipsometer

The nitric oxide post-deposition oxidation anneal removes the CV kink and reduces the density of defects at the interface (Dit). Thus, from the data presented, best results are obtained when the film is subjected to both a pre-treatment and post-treatment, and specifically an 800° C. nitric oxide pre-treatment and a 600° C. nitric oxide post anneal.

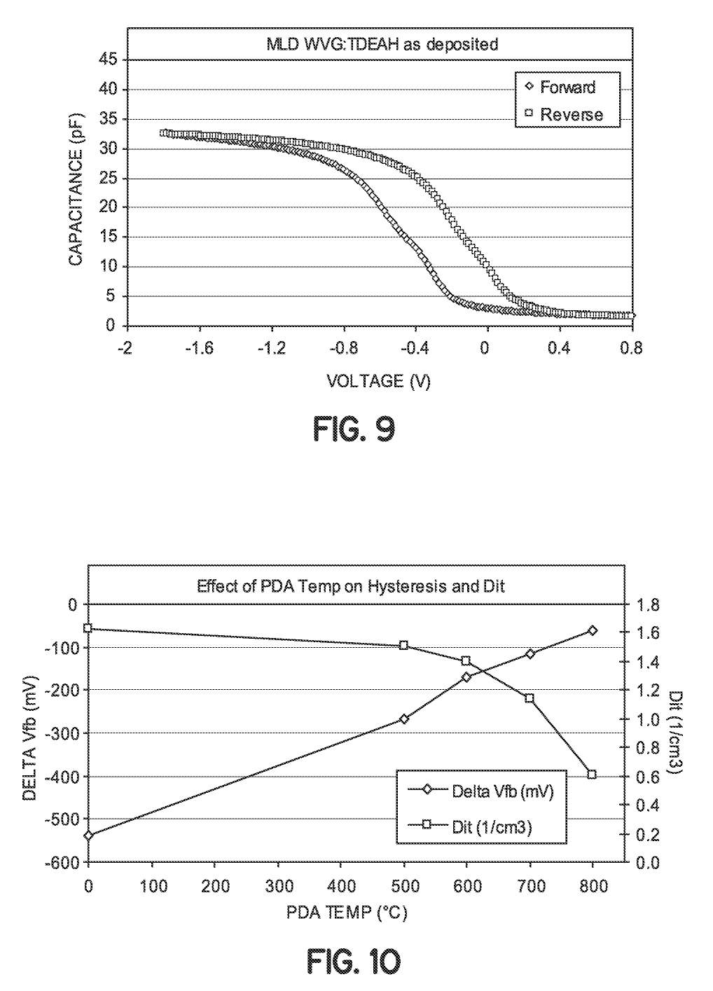

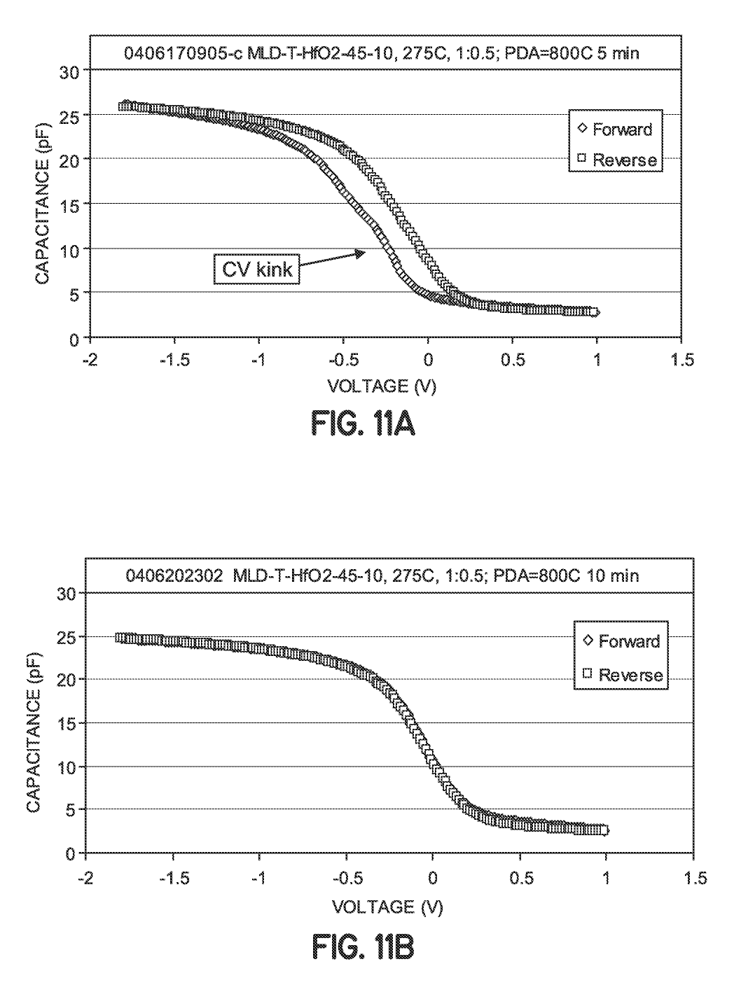

FIG. 9 graphically depicts CV for an HfO₂ film deposited from TDEAH with H₂O vapor from a water vapor generator (WVG) as the oxidizer. The parameters for the MLD process were identical to those set forth above with reference to FIG. 6A, but excluding the post-deposition anneal. In the as-deposited TDEAH film, the hysteresis is very large, as is the density of defects at the interface (Dit). The film was then subjected to a post-deposition anneal (PDA) with N₂ for 10 minutes. FIG. 10 graphically depicts the change in the amount of hysteresis (Delta Vfb) and the density of defects at the interface (Dit) as a function of the PDA temperature, which was varied from 500-800° C. The post-deposition anneal resulted in a decrease in both the hysteresis and density of defects at the interface, with the decrease for each becoming greater with increasing PDA temperature. FIGS. 11A-11B graphically depict the change in CV as a function of the length of the PDA. Specifically, in FIG. 11A, the deposited film was subjected to a PDA in N₂ at 800° C. for 5 minutes, which resulted in a significant reduction in the amount of hysteresis, as shown by comparing FIG. 11A to FIG. 9. In FIG. 11B, the length of time for the PDA was increased to 10 minutes, which almost eliminated the amount of hysteresis.

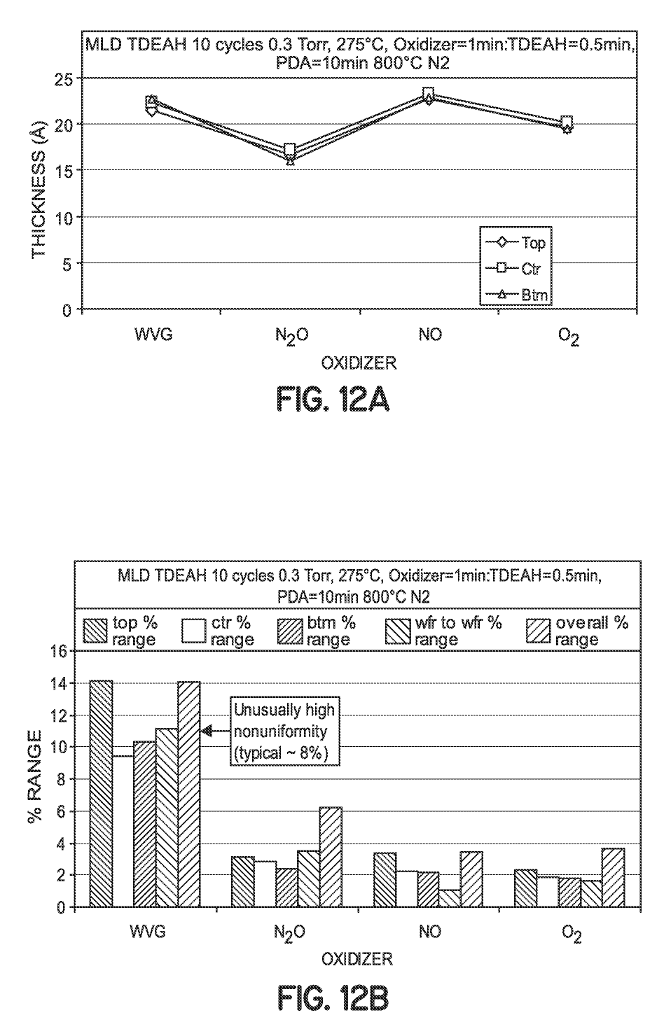

FIGS. 12A-12B graphically depict thickness uniformity as a function of oxidizer type for the TDEAH precursor. The process parameters were identical to that described above with reference to FIG. 6A, with the exception that the type of oxidizer was varied. Water vapor from a water vapor generator, N₂O, NO, and O₂ were used as the oxidizer in alternating pulses with the TDEAH precursor, and uniformity was measured in the top portion of the wafer boat, the center portion of the wafer boat, and the bottom portion of the wafer boat. The water vapor has the highest non-uniformity of the four oxidizers, and in this particular test run, the non-uniformity for the water vapor was even higher than normally observed. The N₂O, NO and O₂ all exhibited good uniformity, with NO and O₂ exhibiting the best results.

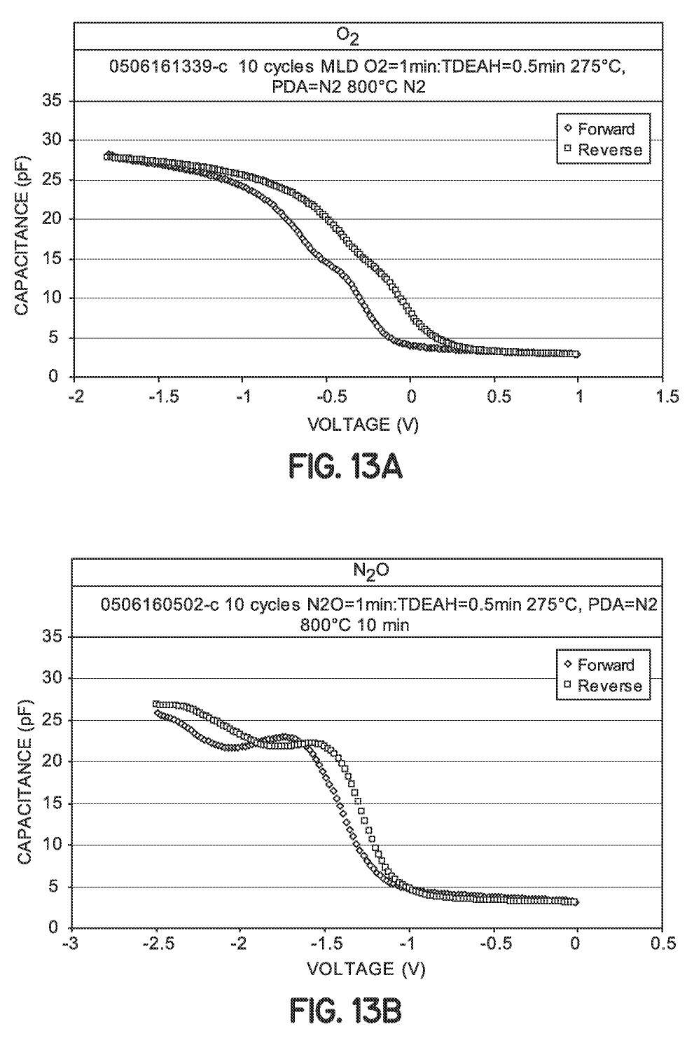

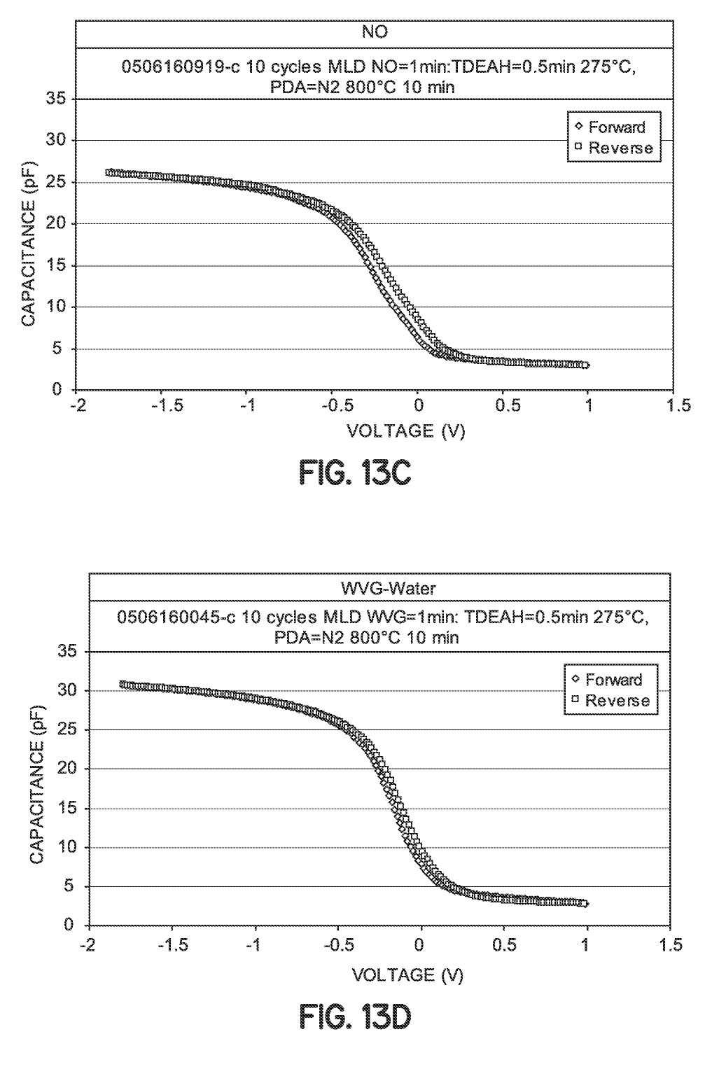

FIGS. 13A-13D graphically depict CV as a function of oxidizer type for the TDEAH precursor. The same process parameters were used as described above with reference to FIGS. 12A-12B. In addition to plotting the CV results in FIGS. 13A-13D, the numerical values for the electrical performance are provided in the following table:

Effect of Oxidizer on MLD HfO₂ with TDEAH

| | Physical | | | | | Dit | Jl |
|---|---|---|---|---|---|---|---|
| | Thickness | EOT | | Vfb | ΔVfb | (cm−3) | at Vfb-1 |
| Oxidizer | (Å) | (Å) | K | (volts) | (mV) | E-12 | (A/cm2) |
| O2 | 20.0 | 14.4 | 5.4 | −0.44 | −250 | −1.61 | 0.7 |
| N2O | 17.3 | 17.3 | 3.9 | −1.40 | −141 | 5.00 | 4.8 |
| NO | 23.1 | 16.0 | 5.6 | −0.19 | −107 | 0.98 | 0.3 |
| WVG | 22.0 | 11.8 | 7.2 | −0.18 | −65 | 0.66 | 0.2 |

As the data shows, use of water vapor and NO as the oxidizer provided similar CV performance, with both exhibiting a low amount of hysteresis. The leakage data tracked the physical thickness. Typically, the leakage increases as the thickness decreases, but the films deposited using water vapor and NO as the oxidizer had a lower than expected leakage for the thickness. The density of defects at the interface was best in the case of water vapor as the oxidizer, but improved results would be expected for each oxidizer if the operating parameters are optimized for each oxidizer with respect to temperature, pressure, exposure time, and post-deposition anneal conditions.

Atomic force microscopy was used to evaluate microroughness of the films deposited using TDEAH with the various oxidizers. The microroughness values in nanometers are provided in the following table:

Atomic Force Microscopy of TDEAH MLD with Various Oxidizers

| | | | 500 nm scan | | | 10 micron scan | | |
|---|---|---|---|---|---|---|---|---|
| AFM Oxidizer | run # | Wfr # | Ra | Rrms | Rmax | Ra | Rrms | Rmax |
| O2 | 0506161339 | 5060601-11 | 0.106 | 0.133 | 1.141 | 0.077 | 0.097 | 0.932 |
| N2O | 0506160502 | 5060601-05 | 0.106 | 0.133 | 1.092 | 0.081 | 0.101 | 0.986 |
| NO | 0506160919 | 5060601-08 | 0.06 | 0.075 | 0.71 | 0.051 | 0.064 | 1.528 |
| WVG | 0506160045 | 5060601-02 | 0.131 | 0.165 | 1.386 | 0.103 | 0.129 | 1.209 |

This data reveals that all film surfaces were relatively smooth.

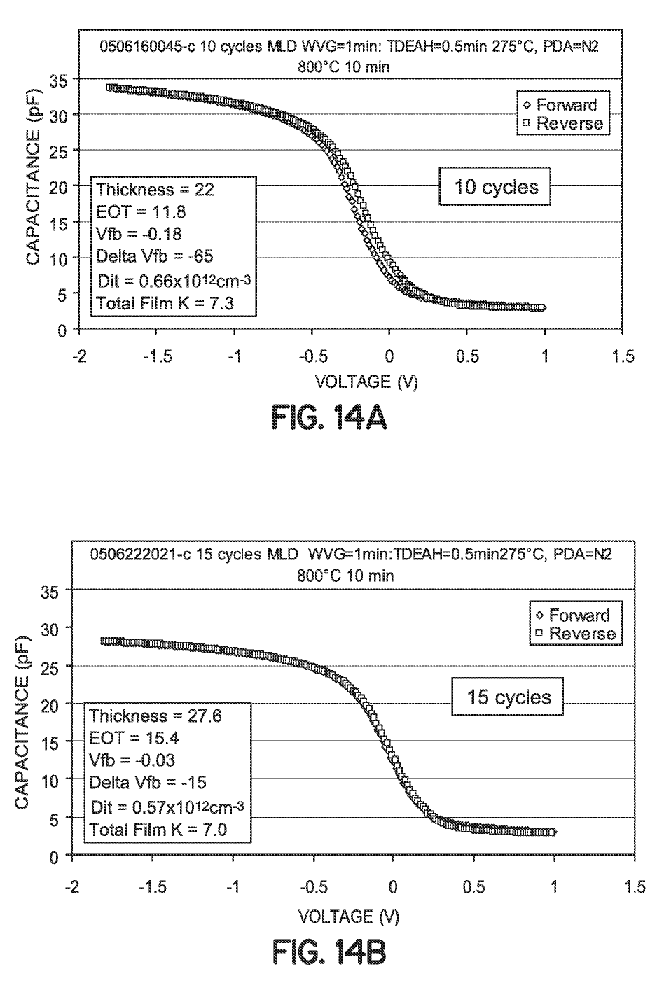

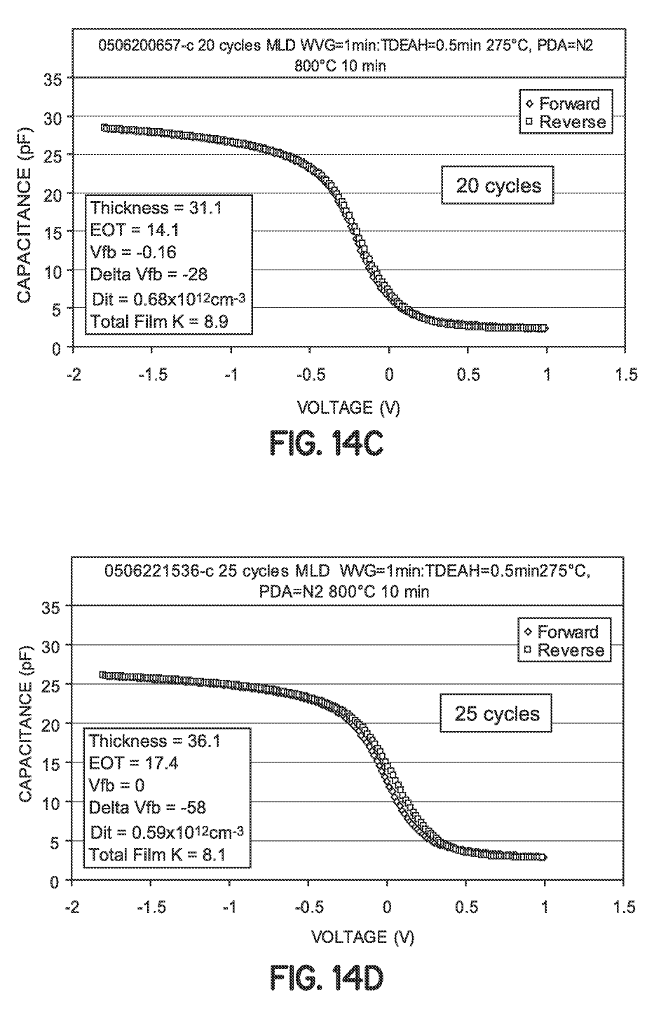

FIGS. 14A-14D graphically depict CV as a function of number of cycles for the TDEAH precursor with H₂O vapor as the oxidizer. The deposition parameters were identical to that described above with respect to FIG. 6A, but with the number of cycles varied between 10 cycles and 25 cycles, in 5 cycle increments. The dielectric constants (k values) were all between 7 and 9, although k values have been observed to increase to 13 for much thicker films.

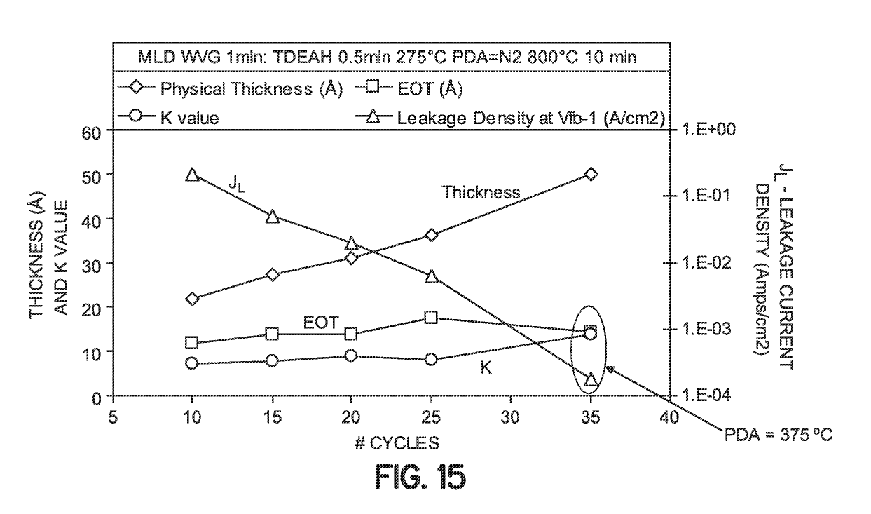

FIG. 15 graphically depicts physical thickness, EOT, dielectric constant (k value) and leakage current density (J_{L}) as a function of number of cycles for the TDEAH precursor with H₂O vapor as the oxidizer. Again, the process parameters were identical to that described above with reference to FIG. 6A, but with the number of cycles varying in 5 cycle increments from 10 to 35. The deposition rate was 0.9 Å per cycle at these deposition conditions. The leakage current density decreases with the physical thickness of the film, and the k values range from 7 to 13 in this thickness range.

In summary, a fast ramping batch furnace with a large temperature range is effective for in-situ formation of high-k film stacks. In addition, films deposited using the HTB precursor are better electrically, as deposited, than films deposited using the TDEAH precursor. However, the TDEAH precursor films have better uniformity than the HTB films. With either precursor, electrical performance and uniformity can each be optimized through selection of the type of oxidizer, the substrate temperature, the chamber pressure, the exposure times, the number of cycles, and the times and temperatures for the pre-treatments and post-treatments. By eliminating transfer of the wafers between process chambers between pre-deposition oxidation treatment, atomic (or molecular) layer deposition, and post-deposition annealing, and by selecting TDEAH or HTB with an appropriate oxidizer and other process parameters, films exhibiting good uniformity and electrical properties can be obtained with a significant reduction in processing time.

While the invention has been illustrated by the description of one or more embodiments thereof, and while the embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method and illustrative examples shown and described. Accordingly, departures may be made from such details without departing from the scope of the general inventive concept.

What is claimed is:

1. An in situ method for forming a HfO₂ high-k dielectric layer in a batch wafer processing system, comprising:
loading a plurality of wafers into a process chamber;
pre-treating the plurality of wafers in the process chamber with a first oxidizer selected from an oxygen-containing gas or an oxygen- and nitrogen-containing gas;
after the pre-treating, and without removing the plurality of wafers from the process chamber, depositing HfO₂ on the plurality of wafers by atomic layer deposition comprising a plurality of deposition cycles, each cycle comprising alternating exposure of the plurality of wafers in the process chamber to a second oxidizer and a hafnium precursor with optional purging in-between, wherein the second oxidizer is selected from an oxygen-containing gas or an oxygen- and nitrogen-containing gas, and wherein the hafnium precursor is selected from hafnium tert-butoxide (HTB) or hafnium tetra-diethylamide (TDEAH); and
unloading the plurality of wafers from the process chamber.

2. The method of claim 1 wherein the process chamber is purged between each alternating exposure and between each deposition cycle with an inert gas.

3. The method of claim 1 wherein the inert gas is H₂ or Ar.

4. The method of claim 1 wherein the first oxidizer is different than the second oxidizer, and each are selected from O₂, O₃, N₂O, NO, or H₂O vapor.

5. The method of claim 1 wherein the pre-treating is performed at a wafer temperature in the range of about 500-1000° C. for a period of about 30 seconds to about 30 minutes.

6. The method of claim 1 wherein the pre-treating is performed at a wafer temperature in the range of about 600-850° C. for a period of about 5-20 minutes.

7. The method of claim 1 wherein the depositing is performed at a wafer temperature in the range of about 25-800° C. for 5-50 deposition cycles, with each alternating exposure being for a period of about 5 seconds to about 5 minutes.

8. The method of claim 1 wherein the depositing is performed at a wafer temperature in the range of about 175-350° C. for 10-25 deposition cycles, with each alternating exposure being for a period of about 15 seconds to about 2 minutes.

9. The method of claim 8 wherein the period of exposure to the second oxidizer is twice as long as the period of exposure to the hafnium precursor.

10. The method of claim 1 further comprising, prior to unloading the plurality of wafers from the process chamber, annealing the plurality of wafers at a temperature in the range of about 250-1000° C. to densify the HfO₂.

11. The method of claim 1 further comprising, prior to unloading the plurality of wafers from the process chamber, annealing the plurality of wafers to densify the HfO₂ wherein the annealing is selected from one or any sequential combination of:
(a) a high temperature bake at a temperature in the range of about 500-1000° C. with no gaseous environment;
(b) a high temperature oxidation anneal at a temperature in the range of about 500-1000° C. in the presence of a third oxidizer selected from an oxygen-containing gas or an oxygen- and nitrogen-containing gas; or
(c) a high temperature anneal at a temperature in the range of about 500-1000° C. in the presence of a non-oxidizing gas.

12. The method of claim 11 wherein the temperature in (a), (b), or (c) is 550-800° C.

13. The method of claim 11 wherein the annealing is (b) at a temperature of 600° C. and the third oxidizer is NO.

14. The method of claim 11 wherein the annealing is (c) at a temperature of 800° C. and the non-oxidizing gas is N₂.

15. The method of claim 1 further comprising, prior to unloading the plurality of wafers from the process chamber, annealing the plurality of wafers to densify the HfO₂ wherein the annealing is selected from one or any sequential combination of:
(a) a low temperature bake at a temperature in the range of about 250-450° C. with no gaseous environment;
(b) a low temperature oxidation anneal at a temperature in the range of about 250-450° C. in the presence of a third oxidizer selected from an oxygen-containing gas or an oxygen- and nitrogen-containing gas; or
(c) a low temperature anneal at a temperature in the range of about 250-450° C. in the presence of a non-oxidizing gas.

16. An in situ method for forming a HfO₂ high-k dielectric layer in a batch wafer processing system, comprising:
loading a plurality of wafers into a process chamber;
pre-treating the plurality of wafers in the process chamber at a wafer temperature in the range of about 600-850° C. with a first oxidizer selected from O₂, O₃, N₂O, NO, or H₂O vapor;
after the pre-treating, and without removing the plurality of wafers from the process chamber, depositing HfO₂ on the plurality of wafers by atomic layer deposition comprising a plurality of deposition cycles, each cycle comprising alternating exposure of the plurality of wafers in the process chamber at a wafer temperature in the range of about 175-350° C. to a second oxidizer and a hafnium precursor with optional purging in-between, wherein the second oxidizer is selected from O₂, O₃, N₂O, NO, or H₂O vapor, and wherein the hafnium precursor is selected from hafnium tert-butoxide (HTB) or hafnium tetra-diethylamide (TDEAH);
after the depositing, and without removing the plurality of wafers from the process chamber, annealing the plurality of wafers at a temperature in the range of about 550-800° C. to densify the HfO₂, wherein the annealing is selected from one or any sequential combination of a bake with no gaseous environment, an oxidation anneal in the presence of a third oxidizer selected from O₂, O₃, N₂O, NO, or H₂O vapor; or an anneal in the presence of a non-oxidizing gas; and
unloading the plurality of wafers from the process chamber.

17. The method of claim 16 wherein the third oxidizer is NO, and the non-oxidizing gas is N₂.

18. The method of claim 16 wherein the period of exposure to the second oxidizer is twice as long as the period of exposure to the hafnium precursor.

19. The method of claim 16 wherein the annealing includes the oxidation anneal, the first and third oxidizers are NO, the second oxidizer is O₂, and the hafnium precursor is HTB.

20. The method of claim 16 wherein the annealing includes the anneal in the presence of a non-oxidizing gas, the first oxidizer is NO, the second oxidizer is water vapor, the hafnium precursor is TDEAH, and the non-oxidizing gas is N₂.
